(19) United States
(12) Patent Application Publication
(10) Pub. No.: US 2010/0244869 A1
(43) Pub. Date: Sep. 30, 2010

(54) PROBE FOR ELECTRICAL INSPECTION, METHOD FOR FABRICATING THE SAME, AND METHOD FOR FABRICATING A SEMICONDUCTOR DEVICE

(75) Inventors: Masayuki UCHIDA, Kanagawa-ken (JP); Kazuhito Higuchi, Kanagawa-ken (JP); Tomohiro Iguchi, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Toshiba, Tokyo (JP)

(21) Appl. No.: 12/731,609

(22) Filed: Mar. 25, 2010

(30) Foreign Application Priority Data
Mar. 25, 2009 (JP) P2009-073272

(51) Int. Cl. G01R 31/02

(52) U.S. Cl. 324/754

(57) ABSTRACT

An aspect of the present disclosure, there is provided An electrical inspection probe, including, a leading end portion of the electrical inspection probe, the leading end portion contacting with a solder bump located outward the electrical inspection probe, a base material configured at the leading end portion, the base material being constituted with a conductive material, a gold layer on a surface of the base material at least in the leading end portion, a rhodium layer on a surface of the gold layer at least in the leading end portion, and a ruthenium layer on a surface of the rhodium layer at least in the leading end portion.

### CROSS REFERENCE TO RELATED APPLICATION

This application is based upon and claims the benefit of priority from prior Japanese Patent Application No. 2009-073272, filed on Mar. 25, 2009, the entire contents of which are incorporated herein by reference.

### TECHNICAL FIELD

Exemplary embodiments described herein relate to an electrical inspection probe, a method for fabricating the electrical inspection probe, and a method for fabricating a semiconductor device.

### BACKGROUND

An electrical inspection is essential in fabricating processes of semiconductor devices such as large scale integrated circuit (LSI) chips or the like. The electrical inspection evaluates prescribed characteristics of the LSI are realized or not. In the electrical inspection, the LSI is connected to a test substrate through a probe card, so signals are input and output into the LSI from the test substrate.

A plurality of probes are provided in the probe card. One end of each probe is pressed to a solder bump connected to the LSI, and the other end is pressed to an electrode of the test substrate, so that the solder bump of the semiconductor device and the electrode of the test substrate are one-on-one connected.

Furthermore, when a burn-in test is performed as an acceleration test, the semiconductor device and the test substrate are inserted into a thermostatic bath in a state with maintaining the connection through the probe card. Electrical characteristics of the semiconductor device are evaluated with applying thermal stress to the semiconductor device. For example, a probe is constituted with a higher conductive material, a copper alloy as disclosed in JP-A 2004-294063.

However, the leading end of the probe is pressed to the solder bump in such an electrical inspection approach, therefore, a problem which the solder is adhered to the leading end of the probe is generated. The adhered solder on the leading end of the probe is oxidized or is transformed into a metal compound with the probe material, so that a contact resistance between the probe and the solder bump is increased.

Especially, the phenomenon is markedly generated in the burn-in test in which thermal stress is applied to the probe and the solder bump. Furthermore, the probe cannot be used when the contact resistance is over an allowable range. In such a manner, a problem which the conventional probe has a short life time has been included in the technology described above.

### SUMMARY

An aspect of the present disclosure, there is provided an electrical inspection probe, comprising, a leading end portion of the electrical inspection probe, the leading end portion contacting with a solder bump located outward the electrical inspection probe, a base material configured at the leading end portion, the base material being constituted with a conductive material, a gold layer on a surface of the base material at least in the leading end portion, a rhodium layer on a surface of the gold layer at least in the leading end portion, and a ruthenium layer on a surface of the rhodium layer at least in the leading end portion.

Further, another aspect of the present disclosure, there is provided a method for manufacturing an electrical inspection probe, including, preparing a base material constituted with conductive material, forming a leading end portion at an end portion of the base material, forming a gold layer on a surface of the base material, forming a rhodium layer on a surface of the gold layer at least in the leading end portion, and forming a ruthenium layer on a surface of the rhodium layer at least in the leading end portion.

Further, another aspect of the present disclosure, there is provided A method for manufacturing a semiconductor device, including contacting a leading end portion of an electrical inspection probe to a solder bump of an LSI; and performing an electrical inspection on the LSI, the electrical inspection probe including, a base material constituted with a conductive material, a gold layer on a surface of the base material, a rhodium layer on a surface of the gold layer at least in the leading end portion of the base material, a ruthenium layer on a surface of the rhodium layer at least in the leading end portion of the base material.

### BRIEF DESCRIPTION OF THE DRAWINGS

FIG. 1 is a cross-sectional schematic view showing an electrical inspection probe according to a first embodiment of the present invention;

FIG. 2 is a partially enlarged perspective view showing a leading end portion of a wafer connection pin in the electrical inspection probe according to the first embodiment;

FIG. 3A is a partially enlarged schematic view showing an area A shown in FIG. 1, and FIG. 3B is a partially enlarged schematic view showing an area B shown in FIG. 1 according to the first embodiment;

FIG. 4 is a cross-sectional schematic view showing an electrical inspection probe according to a modification in the first embodiment;

FIG. 5 is a flow chart showing a method for fabricating an electrical inspection probe according to a second embodiment of the present invention;

FIG. 6 is a flow chart showing a method for forming a wafer connection pin according to the second embodiment;

FIGS. 7A-7C are cross sectional schematic views showing a method for fabricating a semiconductor device according to a third embodiment of the present invention;

FIGS. 8A-8B are cross sectional schematic views showing the method for fabricating the semiconductor device according to the third embodiment;

FIG. 9 is a table showing characteristics of candidate materials on a covering layer;

FIGS. 10A-10C are graphs of simulation showing influence of mechanical properties of an interlayer on thermal stress of the covering layer;

FIG. 11 is a table showing characteristics of candidate materials on the interlayer;

FIG. 12 is a table showing a dependence of characteristics of a ruthenium layer on film formation methods;

FIG. 13 is a table showing components of plating solutions for forming rhodium;

FIG. 14 is a graph showing a degradation state of the electrical inspection probe in a burn-in test.

### DETAILED DESCRIPTION

Embodiments of the present disclosure will be described below in detail with reference to the drawings mentioned above.

### First Embodiment

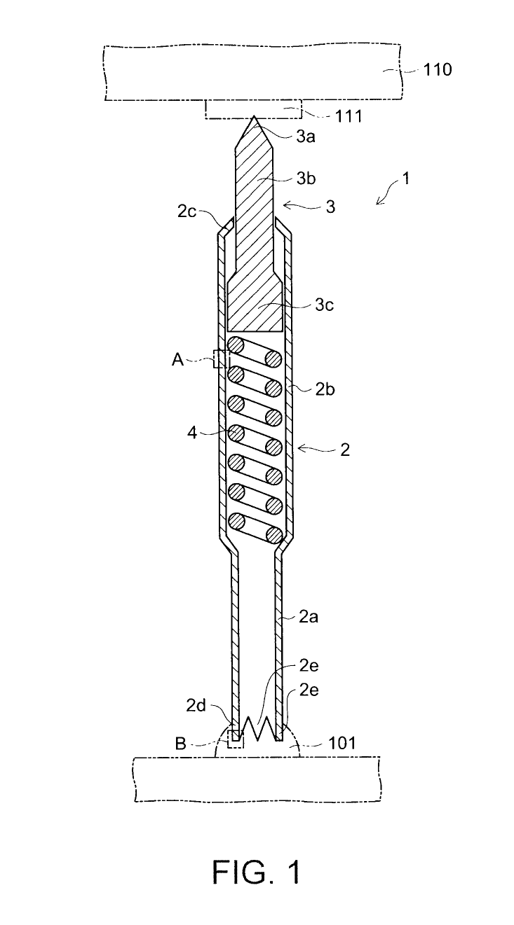

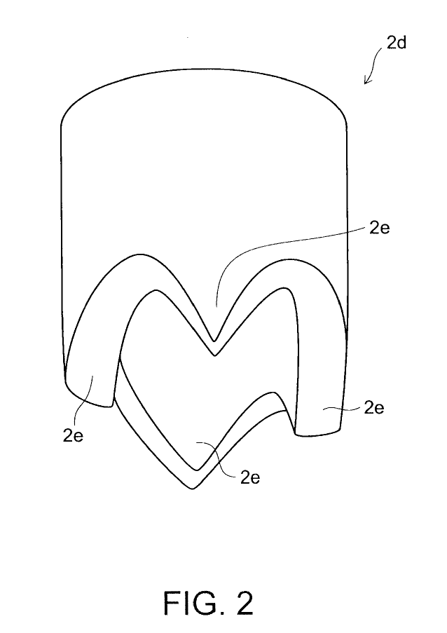

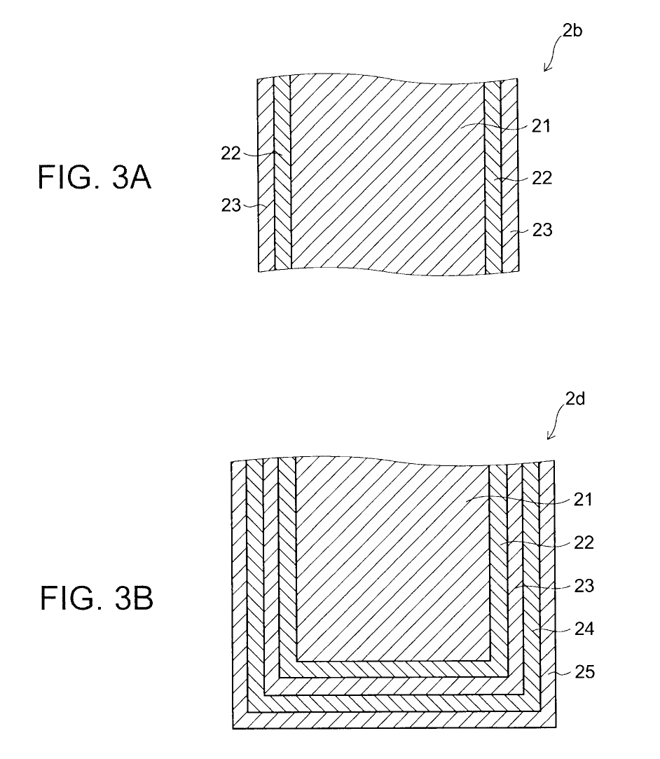

First, a first embodiment of the present invention is explained. The first embodiment shows an example of an electrical inspection probe. FIG. 1 is a cross-sectional schematic view showing the electrical inspection probe. FIG. 2 is a partially enlarged perspective view showing a leading end portion of a wafer connection pin in the electrical inspection probe. FIG. 3A is a partially enlarged schematic view showing an area shown in FIG. 1, and FIG. 3B is a partially enlarged schematic view showing an area B sown in FIG. 1.

As shown in FIG. 1, a wafer connection pin 2, a substrate connection pin 3 and a spring member 4 are provided in an electrical inspection probe 1 (called merely as a probe, hereafter) according to the first embodiment.

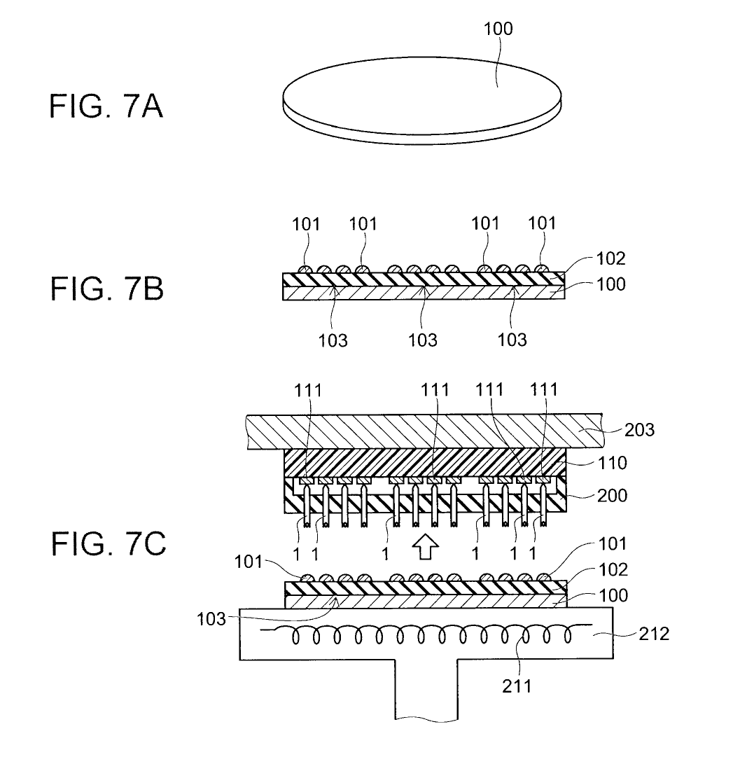

The wafer connection pin 2 has nearly a cylinder shape. On the other hand, a lower portion 2a of the wafer connection pin 2 is narrower than a central portion 2b. A length of lower portion 2a of the wafer connection pin 2 is approximately one third as a ratio in the entire length of the wafer connection pin 2. As shown in FIG. 1 and FIG. 2, a leading end portion 2d in the lower portion 2a of the wafer connection pin 2 is divided into four pieces, for example. Each piece is set in a position which is rotational symmetry through 90 degrees on the wafer central axis of the connection pin 2 and has a peak portion 2e like as nearly a triangle plate. Furthermore, a number of the peak portions 2e is not limited as four. On the other hand, a back end portion 2c of the wafer connection pin 2 is also narrowed to the central portion 2b. The leading end portion 2d of the wafer connection pin 2 is connected to a solder bump 101 on a wafer 100 as referred in FIG. 7 in an inspection process.

The substrate connection pin 3 has nearly a cylindrical shape. On the other hand, a leading end portion 3a of the substrate connection pin 3 is sharp as a circular cone shape, a diameter of a back end portion 3c in the substrate connection pin 3 is larger than a diameter of the central portion 3b. A diameter of a central portion 3b of the substrate connection pin 3 is smaller than an inner diameter of a back end portion 2c in the wafer connection pin 2, diameter back end portion 3c substrate connection pin 3 is larger than an inner diameter of the back end portion 2c in the wafer connection pin 2 and is smaller than an inner diameter of the central portion 2b. The substrate connection pin 3 is constitute with copper or copper alloy, and the entire surface of the substrate connection pin 3, for example, is covered with a gold layer having a phosphorus-doped nickel layer as an underlying layer. The leading end portion 3a of the substrate connection pin 3 is connected to an electrode pad 111 of a test substrate 110 in inspection of the wafer 100.

The spring member 4 has a spiral shape, and is expandable to the longitudinal direction. A diameter of the spring member 4 is entirely smaller than an inner diameter of the central portion 2b in the wafer connection pin 2, and is larger than the inner diameter of the lower portion 2a in the wafer connection pin 2. The spring member 4 is also constituted with copper or copper alloy, and the entire surface of the spring member 4 is covered with, for example, the gold layer having the phosphorus-doped nickel layer as an underlying layer.

The spring member 4 is housed in the wafer connection pin 2, and one end portion 4a of the spring member 4 is locked at a boundary between the central portion 2b of the wafer connection pin 2 and the lower portion 2a. Further, the back end portion 3c of the substrate connection pin 3 is housed in the wafer connection pin 2 as a tube shape.

The central portion 3b and the leading end portion 3a of the substrate connection pin 3 is located at an outer portion of the wafer connection pin 2. As the back end portion 3c of the substrate connection pin 3 is locked at the back end portion 2c of the wafer connection pin 2, the substrate connection pin 3 and the spring member 4 is not unfastened from the wafer connection pin 2.

As shown in FIGS. 3A, 3B, a base material 21 is configured in the wafer connection pin 2. The base material 21 is a base body of a plating layer mentioned above and has the shape of the wafer connection pin 2 mentioned before. The base material 21 is constituted with a conductive material with an superior machining performance, for example, copper, copper alloy such as a beryllium copper (Be—Cu) alloy.

A nickel layer 22 constituted with nickel (Ni), or a nickel compound, for example, a phosphorus-doped nickel (Ni—P) is formed on the base material 21. A film thickness of the nickel layer 22 is, for example, 0.5-3 μm such as 1 μm. The nickel layer 22 is formed by, for example, non-plating. The entire surface of the base material 21, in other words, an inner surface, an outer surface and an end surface are covered with is covered with the nickel layer 22.

A gold layer 23 constituted with gold (Au) is formed on a surface of the nickel layer 22. A film thickness of the gold layer 23 is, for example, 0.5-3 μm such as 2 μm. The gold layer 23 is formed by electro plating, and the entire surface of the base material 21 is covered with the nickel layer 22. An underlying covering layer is formed by the nickel layer 22 and the gold layer 23.

A rhodium layer 24 constituted with rhodium (Rh) or alloy with rhodium and ruthenium (Ru) is formed on a surface of the gold layer 23. A film thickness of the rhodium layer 24 is 1-3 μm such as 2 μm, for example. The rhodium layer 24 is formed by electroplating, for example, using a plating solution including rhodium and ruthenium, for example. A surface of the gold layer 23 is covered with the rhodium layer 24 at the leading end portion 2d of the wafer connection pin 2.

A ruthenium layer 25 constituted with ruthenium (Ru) is formed on the rhodium layer 24. A film thickness of the ruthenium layer 25 is, for example, 0.2-1.5 μm such as 0.4 μm. The ruthenium layer 25 is formed by sputtering. The ruthenium layer 25 is only formed on the rhodium layer 24. Accordingly, the leading end portion 2d of the wafer connection pin 2 is covered.

Next, a behavior of this embodiment is explained.

In accordance with the electrical inspection probe 1 in this embodiment, the leading end portion 2d of the wafer connection pin 2 is contacted to the solder bump 101 of an LSI 103 and the leading end portion 3a of the substrate connection pin 3 is contacted to an electrode pad 111 of a test substrate, when electric characteristics of the LSI 103 on the wafer 100 shown in FIG. 7 are inspected. In such a manner, the probe 1 is pressed to the solder bump 101 and the electrode pad 111 by spring member 4 with a constant pressure. As a result, the connection can be reliably performed without damages on the solder bump 101 and the electrode pad 111.

In the probe 1, the base material 21 of the wafer connection pin 2 is constituted with copper or copper alloy, so that a resistance of the wafer connection pin 2 can be suppressed to be lower. Furthermore, an entire surface of the base material 21 is covered with the gold layer 23, so that the surface of the connection pin 2 is not oxidized and the contact resistance between substrate connections pin 3 and the spring member 4 can be suppressed to be lower. Moreover, the nickel layer 22 configured between the base material 21 and the gold layer 23 act as an underlying layer, so that the adhesion between the base material 21 and the gold layer 23 can be heightened. The effect of the mechanism mentioned above can be provided on the substrate connection pin 3 and the spring member 4 in a similar fashion. In this manner, the probe 1 can connect between the solder bump 101 and the electrode pad 111 with lower electrical resistance.

In the first embodiment, the leading end portion 2d of the wafer connection pin 2 is covered with the ruthenium layer 25. Therefore, a reaction between gold of the gold layer 23 and the solder of the solder bump 101 can be suppressed, so that adhesion of the solder on the leading end portion 2d can be prevented. Furthermore in the first embodiment, the rhodium layer 24 configured between the gold layer 23 and the ruthenium layer 25 relaxes thermal stress between the gold layer 23 and the ruthenium layer 25, so that the adhesion of the ruthenium layer 25 can be heightened.

In such a manner, the entire surface of the wafer connection pin 2 is covered with the gold layer 23, so that oxidation resistance of the wafer connection pin 2 is heightened in this embodiment. The leading end portion 2d covered with the ruthenium layer 25 is hard to adhere to the solder. The nickel layer 22 configured between the base material 21 and the gold layer 23, and the rhodium layer 24 configured between the gold layer 23 and the ruthenium layer 25 are hard to peel off. As a result, an electrical inspection probe with a long life time can be realized in a burn-in test.

In this embodiment, the base material 21 is constituted with copper or copper alloy, for example. However, the base material 21 is not restricted to the above example, but may be constituted with a high conductive and easily-shaped material. For example, the base material 21 may be constituted with iron or iron alloy. When the base material 21 is constituted with a material having good adhesion to the gold layer 23, the nickel layer 22 may not be constituted. Furthermore, the rhodium layer 24 and the ruthenium layer 25 may be formed the entire surface of the wafer connection pin 2. In this case, the uppermost layer of the central portion 2b and the back end portion 2c of the connection pin 2 is constituted with the rhodium layer 24 or the ruthenium layer 25. As rhodium and ruthenium are noble metal, respectively, as the same as gold to be a higher oxidation resistance, a problem cannot be produced.

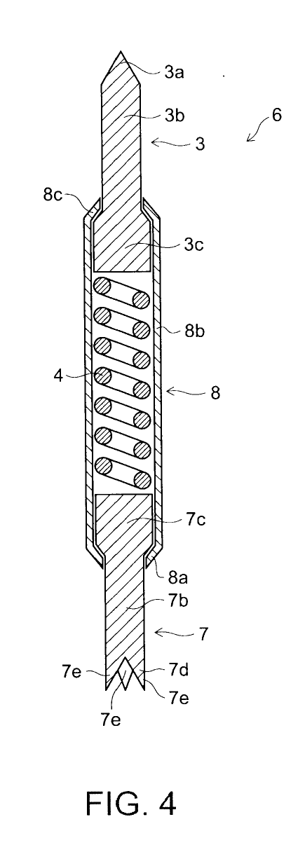

Next, a modification in the first embodiment is explained. FIG. 4 is a cross-sectional schematic view showing an electrical inspection probe according to the modification.

As shown in FIG. 4, a wafer connection pin 7, a tube 8, the substrate connection pin 3 and the spring member 4 are configured in an electrical inspection probe 6 according to this modification. Each structure of the substrate connection pin 3 and the spring member 4 in this modification is the same as the structure of the substrate connection pin 3 and the spring member 4 in the first embodiment.

The wafer connection pin 7 has nearly a cylinder shape and is not midair. A leading end portion 7d of the wafer connection pin 7 is divided into four pieces, for example. A peak portion 7e having a circular cone shape is set in a position which is rotational symmetry through 90 degrees on the wafer central axis of the connection pin 7. Further, a number of the peak portion 7e is not restricted to four. A diameter of a back end portion 7c of the wafer connection pin 7 is larger than a diameter of the central portion 7b.

The tube 8 has nearly a cylinder shape. On the other hand, a leading end portion 8a and a back end portion 8c of the tube 8 are narrower than a central portion 8b. The tube 8 is constituted with copper or copper alloy and the entire surface of the tube 8 is covered with a gold layer having a phosphorus-doped nickel layer as an underlying layer.

A back end portion 7c of the wafer connection pin 7 is housed in the tube 8 and the leading end portion 7a is located in an outer area. The central portion 7b is located at the outer area of the tube 8, when outer stress is not acted. As similarly, the back end portion 3c of the substrate connection pin 3 is housed in the tube 8. Furthermore, the leading end portion 3a is also housed in the tube 8, when outer stress is not acted.

A diameter of the central portion 7b of the wafer connection pin 7 is smaller than an inner diameter of the leading end portion 8a of the tube 8, and a diameter of the back end portion 7c is larger than an inner diameter of the leading end portion 8a, and smaller than an inner diameter of the central portion 8b. As similarly, a diameter of the central portion 3b of the substrate connection pin 3 is smaller than an inner diameter of the back end portion 8c of the tube 8. A diameter of the back end portion 3c is larger than an inner diameter of the back end portion 8c, and is smaller than an inner diameter of the central portion 8b. In such a manner, the back end portion 7c of the wafer connection pin 7 is locked at the leading end portion 8a of the tube 8 and the back end portion 3c of the substrate connection pin 3 is locked at the back end portion 8c of the tube 8. Accordingly, the wafer connection pin 7 and the substrate connection pin 3 is not unfastened from the tube 8.

The spring member 4 is housed in the tube 8. One end portion 4a of the spring member 4 is locked at the back end portion 7c of the wafer connection pin 7, and the other portion 4b of the spring member 4 is locked at the back end portion 3c of the substrate connection pin 3. In such a manner, the spring member 4 is compressed when stress is applied to a direction which the wafer connection pin 7 and the substrate connection pin 3 are approached each other, so that the spring member 4 reversely act as stress which separates these pins.

A plating layer structure of the wafer connection pin 7 is the same as the structure of the wafer connection pin 2 as mentioned in the first embodiment as shown in FIG. 3. For example, the nickel layer, the gold layer, the rhodium layer and the ruthenium layer are formed in an order on the surface of the base material constituted with copper or copper alloy. A structure, an operation and an effect on the modification without mentioned above are the same as the first embodiment.

### Second Embodiment

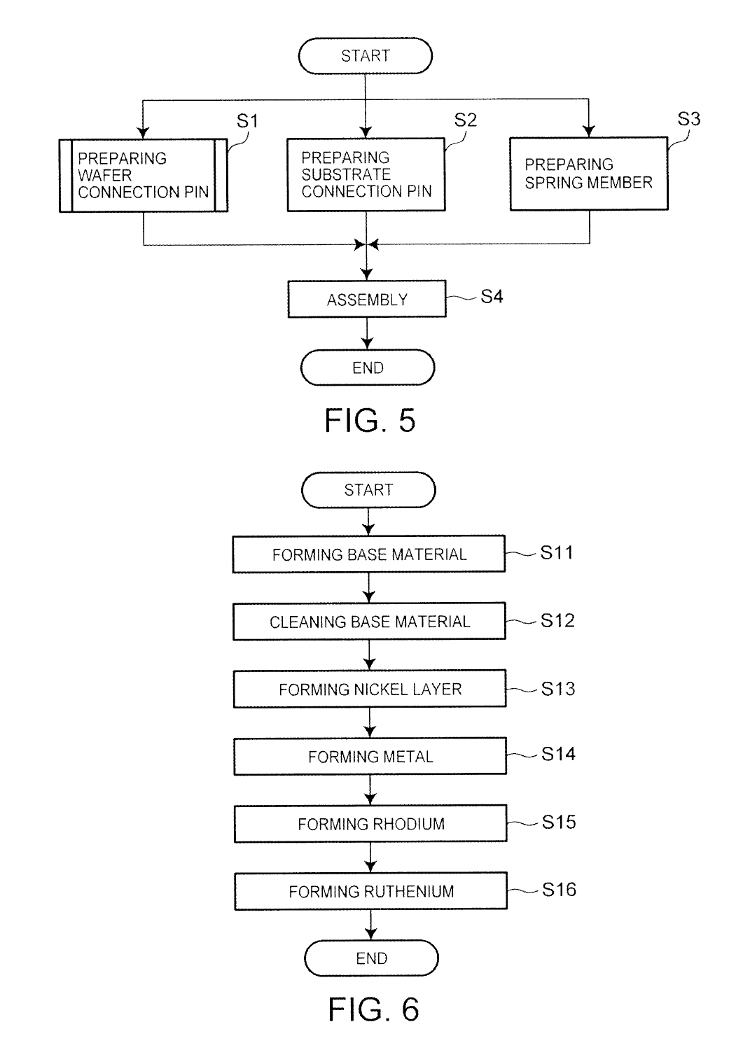

Next, a second embodiment is explained as a method for fabricating the electrical inspection probe according to the first embodiment. FIG. 5 is a flow chart showing the method for fabricating the electrical inspection probe according to the second embodiment. FIG. 6 is a flow chart showing the method for forming a wafer connection pin according to the second embodiment.

The second embodiment is explained as reference to FIGS. 1-3, FIG. 5 and FIG. 6. As shown in step S1 of FIG. 5, the wafer connection pin 2 is fabricated. The method for fabricating the wafer connection pin 2 is explained below in detail.

As shown in step S11 of FIG. 6, a reed-shaped plate material constituted with a conductive material, for example, copper or copper alloy such as a beryllium-copper alloy (Be—Cu) is prepared. The plate material is rounded along lateral direction. The both end portions are connected each other to process as a cylinder shape. Subsequently, diameter of a portion in the cylinder shape is shrunken. The leading end portion is, for example, divided into four pieces to form a peak portion with a triangle plate shape, so that the base material 21 is processed. Further, a back end portion of the base material is not narrowed in this stage.

As shown in step S12, the base material 21 is cleaned. As shown in step S13, a nickel layer 22 constituted with, for example, nickel or nickel alloy such as a phosphorous-doped nickel (Ni—P) is formed on an entire surface of the base material 21 by non-plating, for example. A film thickness of the nickel layer 22 is, for example, 0.5-3 μm such as 1 μm.

As shown in step S14, gold layer 23 constituted with gold (Au), for example, is formed on the entire surface of the nickel layer 22, for example, by electroplating. A film thickness of the gold layer 23 is, for example, 0.5-3 μm such as 2 μm by electroplating, for example. In such a manner, an underlying covering layer constituted with the nickel layer 22 and the gold layer 23 is formed.

As shown in step S15, the rhodium layer 24 constituted with rhodium or ruthenium (Rh) alloy is formed on a surface of the gold layer 23 by electroplating, for example. The rhodium layer 24 is only formed on the leading end portion of the base material 21. A film thickness of the rhodium layer 24, for example, 1-3 μm such as 2 μm.

In the process mentioned above, a plating solution including ruthenium other than rhodium is used. As one example, a plating solution including 1.2 mass % of a rhodium compound, 0.5 mass % of rhodium, 0.02 mass % of a ruthenium compound and 0.01 mass % of ruthenium is used. Namely, the solution includes 2 mass % of ruthenium to rhodium mass %. Such a plating solution is, for example, supper rhodium No. 1 producted by Nippon Electroplating Engineers Co. LTD. Furthermore, in the plating process, a plating solution temperature, for example, is 30° C. and an electric current density is, for example, 0.8 A/dm².

As shown in step S16, for example, the ruthenium layer is formed on a surface of the rhodium layer 24 by sputtering. The leading end portion of the base material 21 is covered with the ruthenium layer 25. A film thickness of the ruthenium layer 25 is, for example, 0.2-1.5 μm such as 0.4 μm. In such a manner, the wafer connection pin 2 is fabricated.

On the other hand, as shown in step S2 of FIG. 5, substrate connection pin 3 is fabricated. Further, as shown in step S3 of FIG. 5, the spring member 4 is fabricated. As shown in step S4 of FIG. 5, the electrical inspection probe is assembled by using the wafer connection pin 2, the substrate connection pin 3 and the spring member 4. Specifically, the spring member 4 is inserted into the wafer connection pin 2 from the back end portion 2c side of the wafer connection pin 2. In the state, the back end portion 2c of the wafer connection pin 2 is narrowed. In such a manner, the spring member 4, the back end portion 3c and the substrate connection pin 3 is housed in the wafer connection pin 2 to be fabricated the electrical inspection probe 1

Next, effect of this embodiment is explained below. The rhodium layer 24 is formed by electroplating in a processing step as shown in step S15 of FIG. 6 in this embodiment and the plating solution including ruthenium other than rhodium. In such a manner, generation of crack and peeling in the rhodium layer 24 after the film formation can be prevented as compared to a film formed by using a plating solution without ruthenium.

The ruthenium layer 25 is formed by sputtering in a processing step as shown in step S16, therefore, the adhesion with the rhodium layer 24 can be improved as compared to a film formed by electroplating. In the processing step of the ruthenium layer 25 by sputtering, impurities such as oxygen or the like is less incorporated, so that crystalline quality of the ruthenium layer 25 is improved to be lower on an internal stress in the ruthenium layer 25.

Furthermore, the rhodium layer is formed by using the plating solution including ruthenium, as example. However, the method is not restricted as mentioned above and can obtain prescribed effect by using a plating solution without ruthenium. The ruthenium layer is formed by using sputtering, as example. However, the method is not restricted as mentioned above and vapor phase deposition, liquid phase deposition, for example, electroplating or the like may be used as the method. As mentioned later in the second embodiment, the internal stress of the ruthenium layer is decreased by sputtering. However, other vapor deposition may also obtain the same effect as sputtering. Furthermore, constant effect can be obtained the ruthenium layer by electroplating or the like.

### Third Embodiment

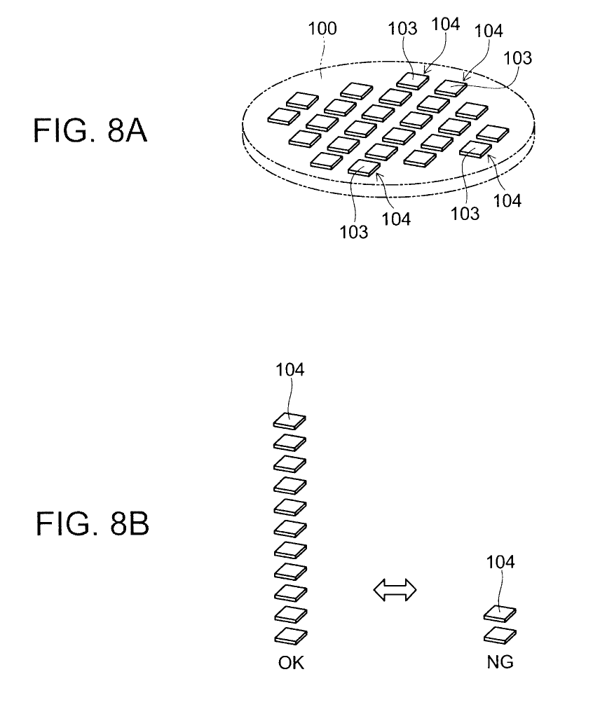

Next, a third embodiment is explained as a method for fabricating a semiconductor device using the electrical inspection probe according to the first embodiment. FIGS. 7A-7C and FIGS. 8A-8C are schematic views showing the method for fabricating the semiconductor device using the electrical inspection probe.

First, as shown in FIG. 7A, a wafer 100 constituted with silicon as a semiconductor wafer, for example, is prepared. An element isolation area (not shown), a diffusion area (not shown) and the like are formed in the wafer 100.

As shown in FIG. 7B, a multilevel wiring layer 102 is formed above the wafer 100. In such a manner, a plurality of LSIs 103 are formed above the wafer 100. Further, the solder bump 101 is formed above the multilevel wiring layer 102 which is connected to the LSIs 103.

As shown in FIG. 7C, an electrical inspection is performed on the LSIs 103. In the inspection, the wafer 100 is disposed on a heater stage 212 having a heater 211. On the other hand, a test substrate 110 is fixed on a lower surface of a holder 203. Each electrode pad 111 is formed at a position corresponding to each solder bump 101 on the lower surface.

A probe card 200 is fixed at a lower surface of the test substrate 110. The plurality of the electrical inspection probes 1 are configured in the probe card 200. The electrical inspection probes 1 are related to the first embodiment mentioned above. The electrical inspection probes 1 are configured at a position corresponding to the solder bumps 101 and the test substrate 110 in the wafer 100. As shown in FIG. 1, the leading end portion 3a of the substrate connection pin 3 in each electrical inspection probe is contacted to the electrode pad 111 of the test substrate 110.

Next, the heater stage is moved upward. In such a manner, as shown in FIG. 1, the solder bump 101 of the wafer 100 is contacted to the leading end portion 2d of the wafer connection pin 2 in the electrical inspection probe 1 disposed on the probe card 200.

In the state, electric characteristics of the LSIs 103 are evaluated by the test substrate 110, while the heater 211 is operated to apply thermal load to the wafer 100. In such a manner, an acceleration test on the LSIs 103 can be performed.

As shown in FIG. 8A, the wafer 100 is diced into a plurality of chips 104 on each LSI 103. As shown in FIG. 8B, the chips 104 are sorted into OK or NG on the basis of the inspection as shown in FIG. 8B.

Next, effect of this embodiment is explained below.

In this embodiment, the electrical inspection probe 1 according to the first embodiment is used in the electrical inspection process as shown in FIG. 7C. The electrical inspection probe 1 has a long lifetime to have less exchanging frequency, so that the electrical inspection of the LSIs 103 is effectively performed. Accordingly, semiconductor devices are fabricated with higher productivity, so that the product cost can be decreased.

In this embodiment, the electrical inspection is collectively performed on the wafer state before dicing. In such a manner, the plurality of the LSIs 103 included in the wafer 100 is inspected in one step to obtain higher effectiveness. The method can also be decreased with the product cost.

### Fourth Embodiment

A fourth embodiment is described for specifically explaining on effect of the embodiments mentioned above. In the forth embodiment, a constitution of the electrical inspection probe according to the first embodiment is explained.

A mechanical constitution of the fourth embodiment is the same as the electrical inspection probe according to the first embodiment. However, a rhodium layer and a ruthenium layer are not configured on the wafer connection pin, but a nickel layer covers the entire surface of the base material constituted with copper alloy. The entire surface of the nickel layer is covered with a gold layer. Namely, the gold layer is exposed on the entire surface of the wafer connection pin in the fourth embodiment.

As mentioned above, the leading end portion of the wafer connection pin is necessary to be contacted with the solder bump, when electric characteristics of the LSI formed on the wafer are inspected. However, the gold layer is reacted with the solder in a cycle of the burn-in tests to generate an inter metallic compound (IMC), when the electrical inspection probe according to this embodiment, in other word, the leading end portion of the wafer connection pin is covered with the gold layer. As a result, a contact resistance between the wafer connection pin and the solder bump is lowered by the reaction.

Therefore, Applicants proposes that the leading end portion of the wafer connection pin is covered with the covering layer. All of the solid materials can be considered as candidates. Accordingly, the candidates are narrowed down by investigations mentioned below.

(Investigation of Covering Layer)

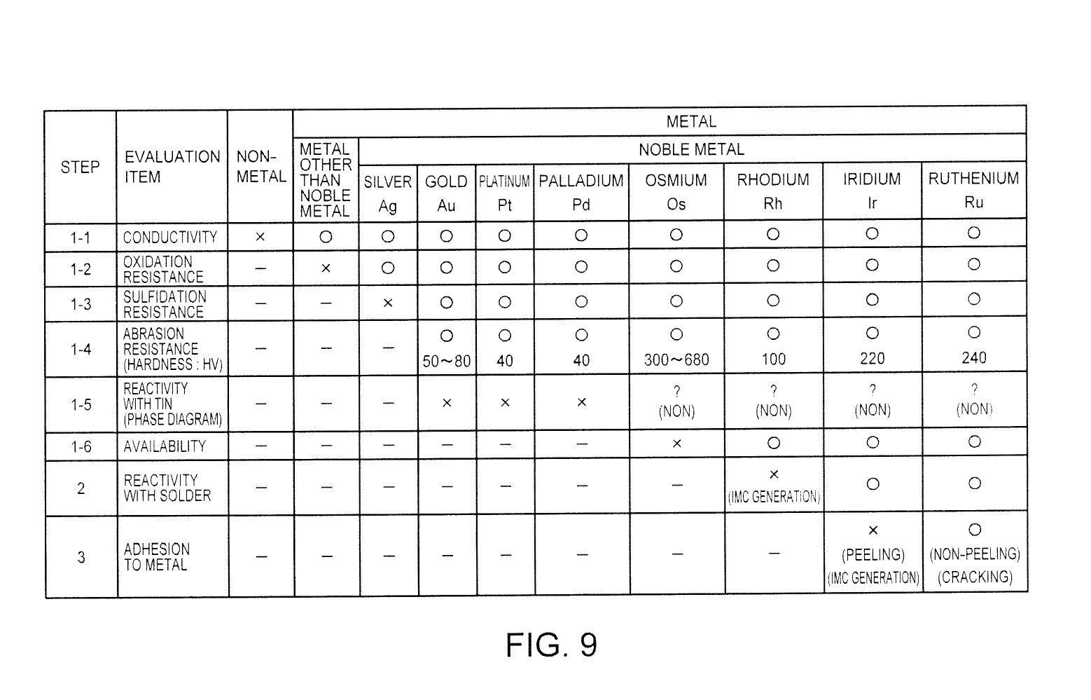

FIG. 9 is a table showing characteristics of candidate materials on a covering layer. In symbols of FIG. 9, the symbol “∘” is excellent in an evaluate item, the symbol “x” is defective, the symbol “?” is unclear, respectively, in the evaluate items. The symbol “−” is not investigated by the evaluate item.

As shown in the investigation step 1-1 of FIG. 9, the candidate materials are restricted to metals, as the covering layer covering the leading end portion of the wafer connection pin is demanded for conductive. Further, as shown in the investigation step 1-2, the candidate materials are restricted to noble metals as the covering layer is demanded for oxidation resistance. Generally, eight kinds of metals, such as silver (Ag), gold (Au), platinum (Pt), palladium (Pd), osmium (Os), rhodium (Rh), iridium (Ir), and ruthenium (Ru) are a group of noble metal.

As shown in the investigation step 1-3, silver (Ag) is omitted from the candidates because an exposed surface of silver (Ag) is easily sulfurized. Further, as shown in the investigation step 1-4, each of the residual candidates of the seven noble metals has higher hardness than tin of HV10 and has no problem as abrasion resistance.

As shown in the investigation step 1-5, reactivity with tin (Sn) included in solder is investigated. Gold (Au), platinum (Pt) and palladium (Pt) is highly reacted with tin included in solder and generating a solid solution or a compound with tin is demonstrated by investigating with reference to conventional phase diagrams. Accordingly, it is considered that solder is easily adhered to the three noble metals, so that the three noble metals are omitted from the candidates. The conventional phase diagrams between tin (Sn) and osmium (Os), rhodium (Rh), iridium (Ir), and ruthenium (Ru) is not appeared, therefore, reactivity with tin (Sn) is unclear. The four noble metals are successively investigated. As shown in the investigation step 1-6, osmium (Os) is difficult to obtain to omit from the candidate materials. From the investigation mentioned above, three kinds of noble metals, (Rh), iridium (Ir) and ruthenium (Ru) are narrowed down as the candidate materials.

As shown in the investigation step 1-2, the experiments are performed on three metals of rhodium (Rh) iridium (Ir) and ruthenium (Ru) for evaluating reactivity with solder. Specifically, covering layer being 0.5 μm thick constituted with each material is formed on a silicon substrate. On the other hand, a solder bump constituted with tin-silver-copper (Sn—Ag—Cu) alloy is formed on a chip size package (CSP). The CSP is applied with ultra-sonic and load at high temperature of 150° C. In the state, the solder bump is pressed to the covering layer and is retained in 100 hours.

In this experimental results, when the covering layer is formed by rhodium (Rh), an intermetallic compound (IMC) is generated with solder. The amount of compound is not as large as the covering layer formed by gold. However, when the covering layer is formed by iridium (Ir) or ruthenium (Ru), the IMC is not generated. On the basis of this experimental results, rhodium (Rh) is omitted from the candidates as the covering layer.

As shown in the investigation step 1-3, experiments on iridium (Ir) and ruthenium (Ru) are performed for evaluating adhesion between the gold layer and the covering layer. Specifically, the covering layer constituted with iridium (Ir) or ruthenium (Ru) is formed on the gold layer in the leading end portion of the wafer connection pin. Further, the electrical inspection probe is formed using the wafer connection pin. Further, the leading end portion of the wafer connection pin is contacted to the solder bump and burn-in test is performed. After the test is finished, a cross section of the leading end portion of the wafer connection pin is observed by scanning electron microscopy (SEM).

As the results mentioned above, the covering layer is peeled off from the gold layer which is reacted with the solder bump to generate an intermetallic compound in the wafer connection pin covered with the covering layer constituted with iridium (Ir) on the gold layer. On the other hand, the covering layer is not peeled off from the gold layer which is not reacted with the solder bump in the wafer connection pin covered with the covering layer constituted with ruthenium (Ru) on the gold layer. However, many cracks are formed in the covering layer.

The investigation mentioned above clearly demonstrates ruthenium (Ru) is optimum as a material for the covering layer. In such a manner, the wafer connection pin without reaction with solder in the burn-in test to strongly adhere with the covering layer can be realized. However, in the investigation step 1-3, cracks are generated in the ruthenium layer in the burn-in test. When cracks are generated, solder may be inserted and be reacted with gold in a long period usage. Therefore, investigation for controlling generation of the cracks is necessary for increasing life time of the electrical inspection probe.

### (Investigation on Interlayer)

The thermal stress applied to the ruthenium layer by the burn-in test probably generates the cracks in the ruthenium layer on the gold layer. Consequently, an interlayer between the gold layer and the ruthenium layer is configured, so that the thermal stress can be relaxed to control the generation of the cracks.

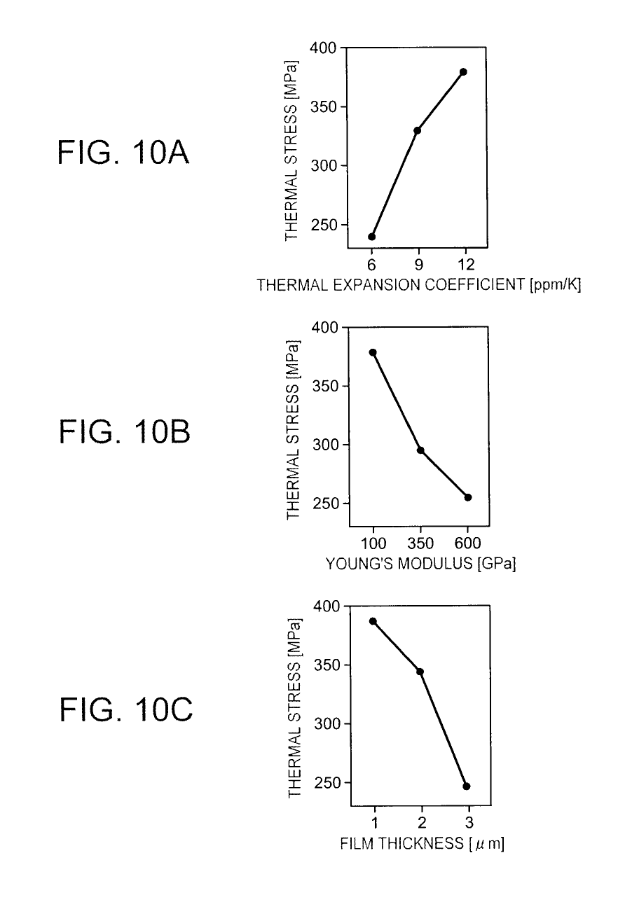

Mechanical properties demanded as an interlayer are investigated by simulation. FIGS. 10A-10C are graphs of the simulation results in which mechanical properties of the interlayer are set as the horizontal axis and the thermal stress of the covering layer (ruthenium layer) is set as the vertical axis. The graphs indicate influences of the mechanical properties of the interlayer on the thermal stress of the covering layer. The horizontal axis of FIGS. 10A-10C show linear expansion coefficient, Young's modulus and film thickness, respectively.

Conditions in the simulation are described below. A base material duplicated a shape of the leading end portion in the wafer connection pin is configured. A multilevel layer is configured on the base material. The multilevel layer is constituted with a nickel layer with the thickness of 1 μm, a gold layer with the thickness of 1 μm, an interlayer with the thickness of 1-3 μm and a ruthenium layer with the thickness of 0.4 μm, in an order. The mechanical properties, linear expansion coefficient, Young's modulus and film thickness of the interlayer are set at standards, respectively. The thermal stress applied to the ruthenium layer at the temperature of 150° C. is calculated. FIGS. 10A-10C show results of the simulation.

As shown in FIGS. 10A-10C, lower linear expansion coefficient, higher Young's modulus and thicker film thickness of the material constituting the interlayer can decrease the thermal stress applied to the covering layer (ruthenium layer). Next, a material preferable as the interlayer is selected.

First, as the ruthenium layer being the covering layer is only formed on noble metal, the material of the interlayer is determined to be a noble metal. In the eight kinds of noble metal mentioned above, as reference to FIG. 9, gold (Au) formed as the underlying layer, ruthenium (Ru) formed as the covering layer, silver (Ag) with lower sulfuric resistance and osmium (Os) being difficult to be obtained are omitted from the candidates of the interlayer material.

As described in the investigation step 1-3, the iridium layer on the gold layer is easily peeled off by a thermal treatment, iridium (Ir) is also omitted.

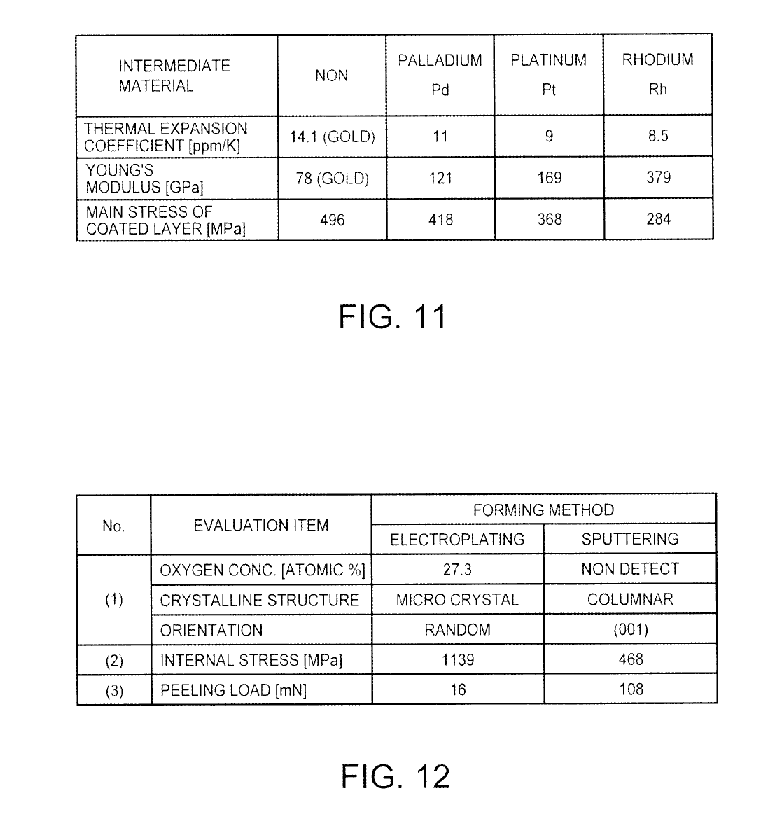

As shown in FIG. 11, the candidate materials on the interlayer is narrowed to palladium (Pd), platinum (Pt), and rhodium (Rh). The table shows mechanical properties of the candidate materials of the interlayer and the simulation results of the thermal stress applied to the covering layer in forming the interlayer.

As shown in FIG. 11, the material with the lowest linear expansion coefficient in palladium (Pd), platinum (Pt), rhodium (Rh) is rhodium and the material with the highest Young's modulus is also rhodium. Accordingly, rhodium is optimum as the interlayer material. Specifically, the simulation mentioned above using the mechanical properties of each material can confirm that the thermal stress applied to the ruthenium layer being the covering layer is the smallest in the case of the interlayer formed by rhodium. Further, the simulation can also confirm that the thermal stress applied to the ruthenium layer with the interlayer becomes smaller than that of the ruthenium layer directly on the gold layer.

As results mentioned above, the electrical inspection probe can be realized with characteristics mentioned below by the rhodium layer on the gold layer as the interlayer and the ruthenium layer on the rhodium layer as the covering layer in the leading end portion of the wafer connection pin. The ruthenium layer is not reacted with solder, the covering layer strongly adhered, and the generation of the cracks is difficult for smaller thermal stress applied to the covering layer in the burn-in test. Actually, such an electrical inspection probe is experimentally fabricated. The results are explained in detail after.

### Fifth Embodiment

Next, a fifth embodiment is explained. As the fifth embodiment, a method for fabricating the electrical inspection probe according to the second embodiment is determined. As described in the first embodiment, reaction between ruthenium and solder is suppressed in the leading end portion of the wafer connection pin when the ruthenium layer is formed on the gold layer. However, the cracks are generated in the ruthenium layer. The rhodium layer as the interlayer is formed between the gold layer and the ruthenium layer, which leads to relieve the thermal stress.

On the other hand, a solution is tried from view points of a processing side in the fifth embodiment. In processing steps of the wafer connection pin, the processes influenced on suppressing the crack generation in the ruthenium layer are forming the covering layer (ruthenium layer) and interlayer (rhodium layer). The two processing steps are investigated below.

### (Investigation on Covering Layer)

As previously described the cracks are generated in the ruthenium layer on the gold layer in the burn-in test. In the first embodiment, the interlayer is investigated from the view point of lowering the thermal stress applied to the ruthenium layer. On the other hand, film formation methods are investigated for lowering internal stress in the second embodiment.

As the film formation methods, electroplating and sputtering are investigated. The rhodium layer is formed on the silicon substrate, subsequently, the ruthenium layer is formed on the rhodium layer by electroplating or sputtering. The ruthenium layer is evaluated by methods mentioned below.

(1) Evaluation of Oxygen Concentration and Crystal Structure of the Ruthenium layer by Transmission Electron Microscopy (TEM)-Energy Dispersive X-ray Spectroscopy (EDX)

(2) Measurement of the Internal Stress the Ruthenium Layer by X-ray diffraction (XRD)

(3) Measurement of the Peeling Load of the Ruthenium layer by Micro Scratch Test

A cross-section of a sample is observed in TEM-EDX. A crystalline lattice strain of the ruthenium layer is measured by sin²ψ method to calculate the internal stress. A load is measured when the ruthenium layer is peeled off in the micro scratch test by providing micro vibration on a diamond indenter which makes a scratch on the surface of the sample during gradually increasing of the load.

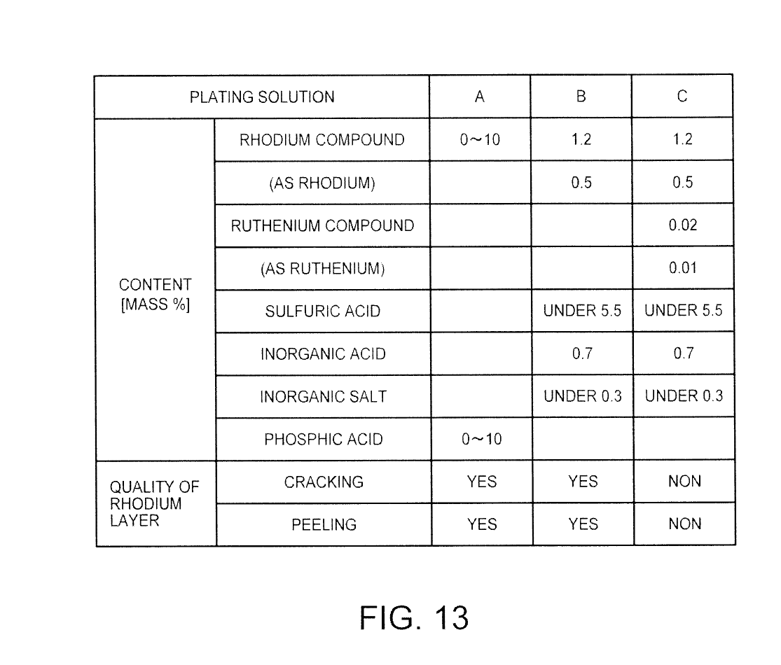

As shown in FIG. 12, the ruthenium layer by electroplating contains a larger amount of oxygen, has a random micro crystal as the crystal structure and has relatively larger internal stress. Further, the peeling load is relatively lower and the adhesion is inferior.

On the other hand, the ruthenium layer by sputtering is not detected with oxygen, has a columnar crystals with (001) oriented structure and has relatively smaller internal stress. Further, the peeling load is relatively higher and the adhesion is superior. As a result, the ruthenium layer by sputtering has less oxygen content to be high purity as compared to the ruthenium layer by the ruthenium layer. Consequently, the ruthenium layer by sputtering has a high crystalline quality to highly align with the rhodium layer, so that the internal stress is lower. Therefore, the adhesion with the rhodium layer becomes higher. From the results mentioned above, sputtering is more suitable than electroplating as the method for forming the covering layer (ruthenium layer).

### (Investigation of Forming Conditions of the Interlayer)

As mentioned in the first embodiment, the rhodium layer is favorable as the interlayer and electroplating is the candidate as the forming method of the rhodium layer. However, candidates of plating solutions are provided. Therefore, effects of the plating solution on influences of the qualities of the rhodium layer are investigated.

The nickel (Ni—P) layer of 1 μm in thickness doped with phosphorous is formed on the surface of the base material shaped as the wafer connection pin formed by non-plating. Further, the gold (Au) layer of 1 μm in thickness is formed on the nickel (Ni—P) layer by electroplating and the rhodium (Rh) layer of 2 μm in thickness is formed on the gold (Au) layer by electroplating. In this case, three kinds of plating solutions as the plating solutions for forming the rhodium layer are prepared as shown in FIG. 13. Further, three kinds of samples are formed by using each plating solution. The cracks and peeling in the rhodium layer are investigated by observing the peak portion of each sample using SEM.

The results are shown in FIG. 13. Contents of each component in the table are values quoted from MSDS.

Further, products and manufacturers on each plating solution are mentioned below.

Plating solution A is RH-W (N. E. CHEMCATN. E. CHEMCAT CO., LTD.). Plating solution B is Rohdex (Electro Engineers of Japan CO., LTD.). Plating solution C is super rhodium No. 1 (Electro Engineers of Japan CO., LTD.).

As shown in FIG. 13 is, the cracks are observed in the rhodium layer in use of the plating solutions A and B. On the other hand, the cracking and peeling are not observed in the rhodium layer in use of the plating solutions. In the plating solution C in difference with the plating solutions A and B, ruthenium is contained 0.01 mass % to the plating solution and 2 mass % to rhodium. In such a manner, quality of the rhodium layer by the plating solution containing ruthenium is superior to that of the rhodium layer by the plating solution containing no ruthenium.

Furthermore, electrical current density of 1.5 A/dm² in electroplating leads to lower internal stress of the rhodium layer than that of 0.5 A/dm² in accordance with another experiment (not described). In such a manner, increasing electrical current density in electroplating prevents the rhodium layer from cracking and peeling. Further, the plating solution temperature of 30° C. leads to lower internal stress of the rhodium layer than that of 70° C. and suppress influence of the electrical current density on the rhodium layer. In such a manner, lowering the plating solution temperature in electroplating prevents the rhodium layer from cracking and peeling to stably form the plating layer.

From the results mentioned above, the rhodium layer having the most superior quality can be formed in the condition using the plating solution C, the plating solution temperature of 30° C. and electrical current density of 1.5 A/dm² in the experiments.

### Sixth Embodiment

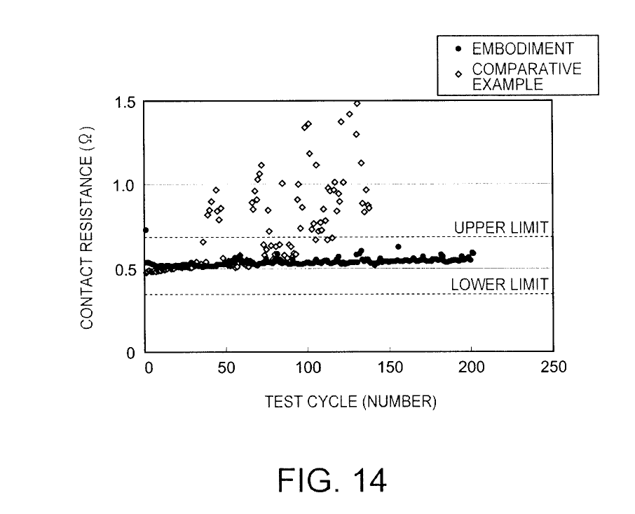

Specifically, the electrical inspection probe is experimentally fabricated on the basis of investigations of the fourth and fifth embodiments and performed in the burn-in test. FIG. 14 is a graph showing a degradation state of the electrical inspection probe in the burn-in test. In FIG. 14, a test cycle is set as the horizontal axis and a contact resistance of the electrical inspection probe is set as the vertical axis.

In a six embodiment, the electrical inspection probe in accordance with the first embodiment is fabricated by the method in accordance with the second embodiment as the electrical inspection probe in accordance with the present invention. When the wafer connection pin is fabricated, the nickel layer constituted with nickel (Ni—P) doped with phosphorous of 1 μm in thickness is formed on the surface of the base material constituted with a beryllium copper (Be—Cu) alloy by non-plating. The gold layer constituted with gold (Au) is formed on the beryllium copper (Be—Cu) alloy by electroplating. The rhodium layer having 2 μm in thickness constituted with rhodium (Rh) or rhodium (Rh)-ruthenium (Ru) alloy in the leading end portion of the wafer connection pin is formed on the gold layer by electroplating. In the plating process, the plating solution C is used as the plating solution, the plating solution temperature is set to beat 30° C., and the electrical current density is set to be at 1.5 A/dm². Subsequently, the ruthenium layer having 0.4 μm thickness constituted with ruthenium (Ru) is formed on the rhodium layer by sputtering.

On the other hand, as the electrical inspection probe according to a comparative example, only the nickel layer and the gold layer in an order are formed on the surface of the base material. Further, a probe is fabricated by using this wafer connection pin.

Next, the burn-in test is performed by the method explained in the third embodiment using the electrical inspection probe. In the test, the uppermost temperature is 200° C. and the lowest temperature is 60° C. in each test cycle, one cycle time is set to be 25.9 min, the current density in the probe is set to be 50 mA, and further, the probe is cleaned one by one on the test cycle. The contact resistance of the leading end portion of the wafer connection pin is measured one by one on the test cycle. FIG. 14 shows the test results. A tolerable range of the contact resistance is within ±30% to the initial value. When the contact resistance is changed to exceed the tolerable range, electric characteristics of LSI cannot be precisely inspected. In the state, lifetime of the probe can be judged to be ended.

As shown in FIG. 14, the contact resistance of the probe according to the comparative example exceeds the tolerable range at nearly 40 cycles. Subsequently, the contact resistance is remarkably fluctuated. On the other hand, the contact resistance of the probe according to the embodiment is within the tolerable range over 200 cycles. In such a manner, the lifetime of the probe according to the embodiment is remarkably longer than the comparative example

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the claims that follow. The invention can be carried out by being variously modified within a range not deviated from the gist of the invention.

What is claimed is:

1. An electrical inspection probe, comprising:
a leading end portion of the electrical inspection probe, the leading end portion contacting with a solder bump located outward the electrical inspection probe;
a base material configured at the leading end portion, the base material being constituted with a conductive material;
a gold layer on a surface of the base material at least in the leading end portion;
a rhodium layer on a surface of the gold layer at least in the leading end portion; and
a ruthenium layer on a surface of the rhodium layer at least in the leading end portion.

2. The electrical inspection probe according to claim 1, wherein
the conductive material is constituted with copper or copper alloy.

3. The electrical inspection probe according to claim 1, further comprising:
a nickel layer configured between the base material and the gold layer, the nickel layer being constituted with nickel or nickel compound.

4. The electrical inspection probe according to claim 3, wherein
film thicknesses of the nickel layer, the gold layer, the rhodium layer and the ruthenium layer are 1 μm, 1 μm, 2 μm and 0.4 μm, respectively.

5. A method for manufacturing an electrical inspection probe, comprising:
preparing a base material constituted with conductive material;
forming a leading end portion at an end portion of the base material;
forming a gold layer on a surface of the base material;
forming a rhodium layer on a surface of the gold layer at least in the leading end portion; and
forming a ruthenium layer on a surface of the rhodium layer at least in the leading end portion.

6. The method according to claim 5, wherein
the conductive material is copper or copper alloy.

7. The method according to claim 5, further comprising:
forming a nickel layer constituted with nickel or nickel compound on a surface of the base material before forming the gold layer.

8. The method according to claim 5, wherein
the ruthenium layer is formed by sputtering.

9. The method according to claim 5, wherein
the rhodium layer is formed by electroplating using a plating solution including ruthenium.

10. The method for manufacturing the electrical inspection probe according to claim 9, wherein
electroplating using the plating solution is performed at a temperature of 30° C.

11. A method for manufacturing a semiconductor device, comprising:
contacting a leading end portion of an electrical inspection probe to a solder bump of an LSI; and
performing an electrical inspection on the LSI;
the electrical inspection probe comprising;
a base material constituted with a conductive material;
a gold layer on a surface of the base material;
a rhodium layer on a surface of the gold layer at least in the leading end portion of the base material;
a ruthenium layer on a surface of the rhodium layer at least in the leading end portion of the base material.

12. The method according to claim 11, further comprising:
forming a plurality of the LSIs is on the semiconductor wafer;
forming a solder bump connected to the LSIs;
performing electrical inspection on the LSIs;
cutting the semiconductor wafer every LSI to separate into a plurality of chips;
selecting the chips on the basis of the electrical inspection;
before performing electrical inspection on the LSI.
